(19) United States
(12) Patent Application Publication
(10) Pub. No.: US 2026/0068046 A1
(43) Pub. Date: Mar. 5, 2026

(54) BONDING STRUCTURE

(71) Applicant: Advanced Semiconductor Engineering, Inc., Kaohsiung (TW)

(72) Inventors: Chih-Jing HSU, Kaohsiung (TW); Hsu-Nan FANG, Kaohsiung (TW)

(73) Assignee: Advanced Semiconductor Engineering, Inc., Kaohsiung (TW)

(21) Appl. No.: 18/817,132

(22) Filed: Aug. 27, 2024

(51) Int. Cl. H05K 1/11; H05K 1/02

(52) U.S. Cl. CPC H05K 1/111; H05K 1/0256; H05K 2201/042; H05K 2201/10734

(57) ABSTRACT

A bonding structure is provided. The bonding structure includes a first substrate, a dielectric layer, a second substrate, a reflowable element, and a dielectric adhesive element. The dielectric layer is over the first substrate. The second substrate is over the first substrate. The reflowable element connects the first substrate to the second substrate. The dielectric adhesive element encapsulates the reflowable element and partially horizontally overlaps the dielectric layer.

### BACKGROUND

### 1. Technical Field

The present disclosure relates generally to a bonding structure.

### 2. Description of the Related Art

As the size of interconnects in a package structure decreases, the pitch of solder bumps of the bonding structure in the package structure decreases as well. A flux is required to remove oxides from the solder bumps before the bonding process; however, the flux may extend into gaps between the solder bumps, and because the gaps are relatively small, residues from the flux may remain on or between the solder bumps. As a result, when an underfill is provided to protect the solder bumps after the bonding process, voids may be formed between the solder bumps and the underfill due to the residues from the flux. Therefore, there is a need to reduce the formation of voids.

### SUMMARY

In one or more arrangements, a bonding structure includes a first substrate, a dielectric layer, a second substrate, a reflowable element, and a dielectric adhesive element. The dielectric layer is over the first substrate. The second substrate is over the first substrate. The reflowable element connects the first substrate to the second substrate. The dielectric adhesive element encapsulates the reflowable element and partially horizontally overlaps the dielectric layer.

In one or more arrangements, a bonding structure includes a first substrate, a second substrate, a reflowable element, a first dielectric layer, and a second dielectric layer. The second substrate is over the first substrate. The reflowable element connects the first substrate to the second substrate. The first dielectric layer extends from the second substrate towards the first substrate. The second dielectric layer is connected to the first dielectric layer and includes a dam structure configured to compensate for the extension amount of the first dielectric layer to reduce a formation of voids.

In one or more arrangements, a bonding structure includes a first substrate, a second substrate, and a solder element. The second substrate is over the first substrate. The solder element connects the first substrate to the second substrate. A lateral surface of the solder element includes a first portion adjacent to the first substrate, a second portion adjacent to the second substrate, and a third portion between the first portion and the second portion. The third portion is concave toward an inner part of the solder element.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a cross-section of a bonding structure in accordance with some arrangements of the present disclosure.

FIG. 1A is a top view of a portion of a bonding structure in accordance with some arrangements of the present disclosure.

FIG. 2 is a cross-section of a bonding structure in accordance with some arrangements of the present disclosure.

FIG. 3 is a cross-section of a bonding structure in accordance with some arrangements of the present disclosure.

FIG. 4A is a cross-section of a bonding structure in accordance with some arrangements of the present disclosure.

FIG. 4B is a cross-section of a bonding structure in accordance with some arrangements of the present disclosure.

FIG. 5A to FIG. 5J illustrate various stages of an exemplary method of forming a bonding structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

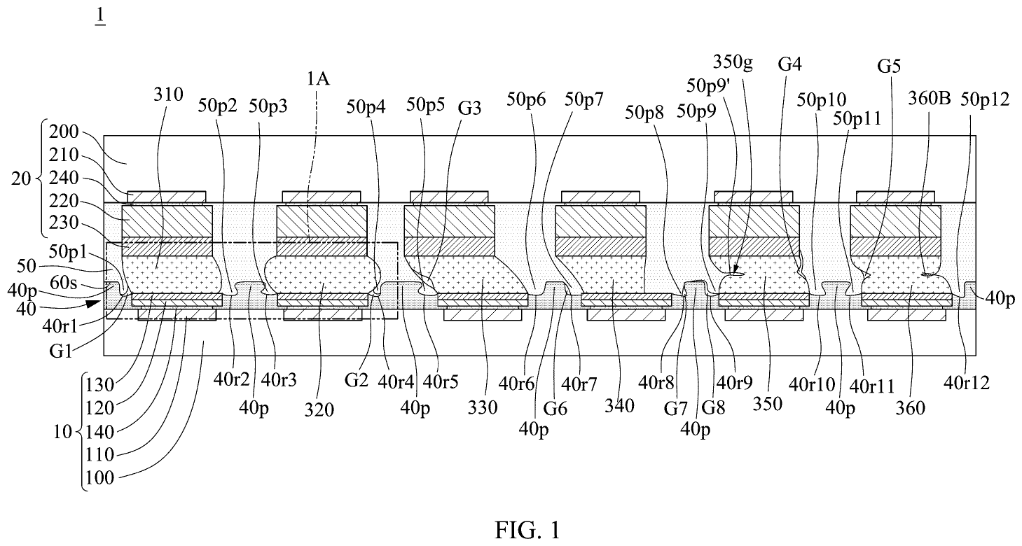

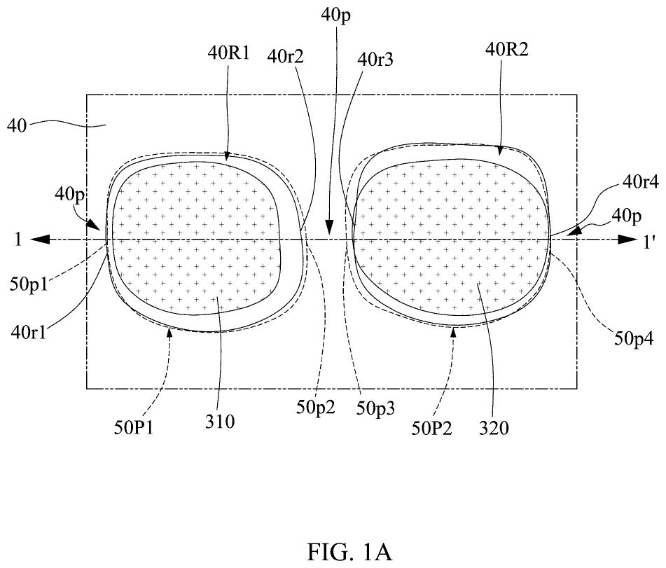

FIG. 1 is a cross-section of a bonding structure 1 in accordance with some arrangements of the present disclosure. The bonding structure 1 may include substrates 10 and 20, one or more bonding elements (e.g., bonding elements 310 to 360), and dielectric layers 40 and 50.

The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, such as a plurality of conductive traces and a plurality of conductive vias. In some arrangements, the substrate 10 includes a ceramic material, a metal plate, an organic substrate, or a leadframe. In some embodiments, the substrate 10 may include a two-layer substrate which includes a core layer and a conductive material and/or structure disposed on an upper surface and a bottom surface of the substrate 10. The conductive material and/or structure may include a plurality of conductive traces.

In some arrangements, the substrate 10 includes a base layer 100, base pads 110, RDL pads 120, barrier layers 130, and seed layers 140. The RDL pads 120 may be used as fan-in structures or fan-out structure. The base pads 110 may be embedded in and exposed by the base layer 100, and the RDL pads 120 may be disposed over and electrically connected to the base pads 110. The base pads 110 may be electrically connected to the interconnection structure in the base layer 100. The barrier layers 130 may be disposed or formed on the RDL pads 120. The RDL pad 120 and the barrier layer 130 may be collectively referred to as a pad structure. The seed layers 140 may be disposed or formed between the base pads 110 and the RDL pads 120. In some arrangements, the seed layer 140 is recessed from one or more lateral surfaces of the RDL pad 120. The base layer 100 may include a semiconductor material (e.g., Si), a dielectric layer, or a combination thereof. The base pads 110 and the RDL pads 120 may be referred to as conductive pads and may include a conductive material such as a metal or metal alloy. Examples include gold (Au), silver (Ag), aluminum (Al), copper (Cu), or an alloy thereof. The barrier layer 130 may include tantalum (Ta), tungsten (W), chromium (Cr), nickel (Ni), gold (Au), tin (Sn), lead (Pb), and/or suitable alloys including at least one of these materials. The seed layer 140 may include titanium (Ti), copper (Cu), nickel (Ni), another metal, or an alloy (such as titanium-tungsten alloy (TiW)). For example, the seed layer 140 may include a Ti layer and a Cu layer stacked over each other.

The substrate 20 may be over the substrate 10. The substrate 20 may include, for example, a printed circuit board, such as a paper-based copper foil laminate, a composite copper foil laminate, or a polymer-impregnated glass-fiber-based copper foil laminate. The substrate 20 may include an interconnection structure, such as a plurality of conductive traces and a plurality of conductive vias. In some arrangements, the substrate 20 includes a ceramic material, a metal plate, an organic substrate, or a leadframe. In some embodiments, the substrate 10 may include a two-layer substrate which includes a core layer and a conductive material and/or structure disposed on an upper surface and a bottom surface of the substrate 20. The conductive material and/or structure may include a plurality of conductive traces.

In some arrangements, the substrate 20 includes a base layer 200, base pads 210, RDL pads 220, barrier layers 230, and seed layers 240. The base pads 210 may be embedded in and exposed by the base layer 200, and the RDL pads 220 may be disposed over and electrically connected to the base pads 210. The base pads 210 may be electrically connected to the interconnection structure or the fan-out RDL in the base layer 200. The barrier layers 230 may be disposed or formed on the RDL pads 220. The RDL pad 220 and the barrier layer 230 may be collectively referred to as a pad structure. The seed layers 240 may be disposed or formed between the base pads 210 and the RDL pads 220. In some arrangements, the seed layer 240 is recessed from one or more lateral surfaces of the RDL pad 220. The base layer 200 may include a semiconductor material (e.g., Si), a dielectric layer, or a combination thereof. The base pads 210 and the RDL pads 220 may be referred to as conductive pads and may include a conductive material such as a metal or metal alloy. Examples include Au, Ag, Al, Cu, or an alloy thereof. The barrier layer 230 may include Ta, W, Cr, Ni, Au, Sn, Pb, and/or suitable alloys including at least one of these materials. The seed layer 240 may include Ti, Cu, Ni, another metal, or an alloy (such as TiW). For example, the seed layer 240 may include a Ti layer and a Cu layer stacked over each other.

In some arrangements, the RDL pads 220 are electrically connected to the RDL pads 120. In some arrangements, the base pads 210 are misaligned with the base pads 110. In some arrangements, the RDL pads 220 are misaligned with the RDL pads 120.

The bonding elements 310, 320, 330, 340, 350, and 360 may be between the substrate 10 and the substrate 20. In some arrangements, the bonding elements 310, 320, 330, 340, 350, and 360 connect the substrate 10 to the substrate 20. The bonding elements 310, 320, 330, 340, 350, and 360 may include one or more reflowable materials (e.g., Ga, In, or the like), soldering materials, or any material having a melting point lower than that of the RDL pads 220 and that of the barrier layers 230. In some arrangements, each of the bonding elements 310, 320, 330, 340, 350, and 360 is or includes a solder element, a solder bump, a solder ball, or the like. The bonding elements may be referred to as reflowable elements. In some arrangements, a pitch of the bonding elements is less than about 15 μm, 10 μm, or 5 μm.

In some arrangements, the bonding elements 310, 320, 330, 340, 350, and 360 connect or electrically connect the RDL pads 120 to the RDL pads 220. In some arrangements, the barrier layers 130 are between the bonding elements 310, 320, 330, 340, 350, and 360 and the RDL pads 120. In some arrangements, the barrier layers 230 are between the bonding elements 310, 320, 330, 340, 350, and 360 and the RDL pads 220.

The dielectric layer 40 may be over the substrate 10. In some arrangements, the dielectric layer 40 is disposed or formed on the substrate 10. In some arrangements, the dielectric layer 40 contacts the base layer 100 and the base pads 110. In some arrangements, the dielectric layer 40 encapsulates the RDL pads 120 and the barrier layers 130. In some arrangements, the dielectric layer 40 contacts at least one the seed layers 140. In some arrangements, the dielectric layer 40 defines a plurality of recesses (e.g., recesses 40r1 to 40r12). In some arrangements, the recesses 40r1 to 40r12 are recessed with respect to one or more top surfaces of the barrier layers 130. In some arrangements, the dielectric layer 40 includes a plurality of dam structures 40p. In some arrangements, the dam structures 40p define the recesses (e.g., the recesses 40r1 to 40r12). In some arrangements, the dam structures 40p are between the bonding elements (e.g., the bonding elements 310 to 360). The dielectric layer 40 may be referred to as an adhesive element, a dielectric adhesive element, or an encapsulant. In some arrangements, a softening temperature (e.g., a glass transition temperature Tg) of the dielectric layer 40 is lower than a melting point of the bonding element 310 to 360. In some arrangements, the dielectric layer 40 includes or is formed of an organic dielectric material, e.g., PI.

The dielectric layer 50 may be over the substrate 10. In some arrangements, the dielectric layer 50 is disposed or formed on the substrate 20. The dielectric layer 50 may extend from the substrate 20 towards the substrate 10. In some arrangements, the dielectric layer 50 contacts the base layer 200 and the base pads 210. In some arrangements, the dielectric layer 50 encapsulates the RDL pads 220 and the barrier layers 230. In some arrangements, the dielectric layer 50 encapsulates the bonding elements 310, 320, 330, 340, 350, and 360. In some arrangements, the dielectric layer 50 is connected to or directly contacts the dielectric layer 40. In some arrangements, the dielectric layer 50 vertically overlaps a portion of at least one of the RDL pads 120. In some arrangements, the dielectric layer 50 vertically overlaps a portion of at least one of the barrier layers 130. In some arrangements, the dielectric layer 50 partially horizontally overlaps the dielectric layer 40. In some arrangements, an interface between the dielectric layer 40 and the dielectric layer 50 includes a wavy profile in a cross-sectional view perspective. In some arrangements, the dielectric layer 50 horizontally overlaps the pad structure of the substrate 10 and covers the pad structure of the substrate 20. The dielectric layer 50 may be referred to as an adhesive element, a dielectric adhesive element, or an encapsulant. In some arrangements, a softening temperature (e.g., a glass transition temperature Tg) of the dielectric layer 50 is lower than a melting point of the bonding element 310 to 360. In some arrangements, the dielectric layer 50 includes or is formed of an organic dielectric material, e.g., PI, a non-conductive film (NCF), or the like. In some arrangements, the dielectric layers 40 and 50 are formed of or include different materials, and an interface 60s is formed between the dielectric layers 40 and 50.

In some arrangements, the dielectric layer 50 partially extends between the dielectric layer 40 (or the dam structures 40p) and the substrate 10. In some arrangements, the dielectric layer 50 partially extends into one or more of the recesses 40r1 to 40r12. In some arrangements, the dielectric layer 50 includes a plurality of portions (e.g., portions 50p1 to 50p12). The portions of the dielectric layer 50 may extend into the recesses of the dielectric layer 40. The portions of the dielectric layer 50 may be filled in the recesses of the dielectric layer 40. The portions 50p1 to 50p12 may be referred to as protrusions. In some arrangements, the dam structures 40p are disposed between the portions 50p1 to 50p12 (or the protrusions) of the dielectric layer 50. In some arrangements, the portions 50p1 to 50p12 extend between the bonding elements and contacting the dielectric layer 40.

Conventionally, a flux is required to remove oxides from solder bumps before a bonding process of the solder bumps is performed. However, the flux may extend into gaps between the solder bumps, and because the gaps are relatively small, residues from the flux may remain on or between the solder bumps. As a result, when an underfill is provided to protect the solder bumps after the bonding process, voids may be formed between the solder bumps and the underfill due to the residues from the flux.

In contrast, according to some arrangements the present disclosure, the dielectric layer 40 and the dielectric layer 50 extend towards each other and compress each other, thereby filling the space between the bonding elements 310 to 360 to protect the bonding elements 310 to 360 from oxidation. Thus, formation of an underfill to protect the bonding elements (e.g., the solder bumps) is omitted, and the processes of applying a flux over the bonding elements and then removing the flux are also omitted. In addition, the dielectric layer 40 and the dielectric layer 50 extend towards each other and compress each other to fill the space between the bonding elements 310 to 360 so as to further reduce the formation of voids (or gaps). As a result, the size and/or number of voids can be reduced from reducing the formation of voids, and thus the area of the pads and the bonding elements exposed to air (or the voids) can be decreased, which in turn reduces the oxidation of the pads and the bonding elements. In some arrangements, the aforesaid underfill includes fillers, and the dielectric layer 50 is free of fillers. As such, the dielectric layer 50 may extends towards and compress the dielectric layer 40 without resistance from any solid content (e.g., fillers), and thus the formation of voids can be further reduced from the compression between the dielectric layers 40 and 50. Therefore, the reliability of the bonding structure 1 can be improved.

In some arrangements, the dielectric layer 50 extends between the bonding elements 310 to 360 and may be unable to completely fill the space between the bonding elements 310, and the dam structures 40p may be configured to compensate for and fill in the space that the dielectric layer 50 extending downwards and unable to fill. In some arrangements, the dam structures 40p are configured to compensate for an extension amount of the dielectric layer 50 to reduce a formation of voids. For example, the dam structures 40p may fill in the space between the bonding elements 310 to 360 to reduce the formation of voids between the dielectric layer 50 and the bonding elements 310 to 360. For example, the dam structures 40p may extend between the portions 50p1 to 50p12 to fill in the space between the portions 50p1 to 50p12 to reduce the formation of voids between the dielectric layer 40 and the dielectric layer 50.

In some arrangements, the portions 50p1 to 50p12 of the dielectric layer 50 may be referred to as first extension structures, and the dam structures 40p of the dielectric layer 40 may be referred to as second extension structures extending between the first extension structures. In the process of connecting the dielectric layer 50 to the dielectric layer 40, the dielectric layer 50 may melt and soften so as to flow toward the dielectric layer 40 and between the dam structures 40p of the dielectric layer 40. Therefore, the dam structures 40p can further compensate for the cover rate (or coverage) of the dielectric layer 50 on the pads of the substrates 10 and 20 and the bonding elements, and thus voids can be further reduced. In some arrangements, the dam structures 40p contact the dielectric layer 50 and are configured to compress the dielectric layer 50 to increase a cover rate of the dielectric layer 50 over the substrates 10 and 20. According to some arrangements of the present disclosure, with the above design to further reduce the size and the number of voids, delamination or cracks resulted from air in the voids that is expanded due to increased temperatures of thermal operations can be omitted.

In some arrangements, the bonding element 310 connects to and contacts the barrier layers 130 and 230. In some arrangements, the portion 50p1 extends into the recess 40r1, and the portion 50p2 extends into the recess 40r2. In some arrangements, the bonding element 310 is partially spaced apart from the portion 50p1 by a gap G1. In some arrangements, the gap G1 is within the recess 40r1. In some arrangements, the gap G1 is filled with air. The gap G1 may be referred to as an air gap, a void, an empty space, or the like. In some arrangements, the bonding element 310 vertically overlaps the portion 50p1. In some arrangements, the RDL pad 220 vertically overlaps the portion 50p1. In some arrangements, the portion 50p2 extends under a portion of the dielectric layer 40 (or the dam structure). In some arrangements, the portion 50p2 extends between the substrate 10 and the dielectric layer 40. In some arrangements, the portion 50p2 extends between the base layer 100 and a portion of the dielectric layer 40. In some arrangements, the portion 50p2 contacts the barrier layer 130. In some arrangements, the portion 50p2 extends between the bonding element 310 and the barrier layer 130. In some arrangements, the portion 50p2 tapers toward the substrate 20 in a cross-sectional view perspective.

In some arrangements, the bonding element 320 connects to and contacts the barrier layers 130 and 230. In some arrangements, the portion 50p3 extends into the recess 40r3, and the portion 50p4 extends into the recess 40r4. In some arrangements, the portion 50p3 extends under a portion of the dielectric layer 40 (or the dam structure). In some arrangements, the portion 50p3 extends between the substrate 10 and the dielectric layer 40. In some arrangements, the portion 50p3 extends between the base layer 100 and a portion of the dielectric layer 40. In some arrangements, the bonding element 320 is partially spaced apart from the portion 50p4 by a gap G2. In some arrangements, the gap G2 is within the recess 40r4. In some arrangements, the gap G2 is filled with air. The gap G2 may be referred to as an air gap, a void, an empty space, or the like. In some arrangements, the bonding element 320 vertically overlaps the portions 50p3 and 50p4. In some arrangements, the portions 50p3 and 50p4 taper toward the substrate 20 in a cross-sectional view perspective.

In some arrangements, the bonding element 330 connects to and contacts the barrier layers 130 and 230. In some arrangements, the portion 50p5 extends into the recess 40r5, and the portion 50p6 extends into the recess 40r6. In some arrangements, the bonding element 330 is partially spaced apart from the dielectric layer 50 by a gap G3. In some arrangements, the bonding element 330 (or the reflowable element) is exposed to the gap G3 (or the void). In some arrangements, the gap G3 is filled with air. The gap G3 may be referred to as an air gap, a void, an empty space, or the like. In some arrangements, the bonding element 330 vertically overlaps the portion 50p5. In some arrangements, the RDL pad 220 vertically overlaps the portion 50p5. In some arrangements, the portion 50p5 extends under a portion of the dielectric layer 40 (or the dam structure). In some arrangements, the portion 50p5 extends between the substrate 10 and the dielectric layer 40. In some arrangements, the portion 50p5 extends between the base layer 100 and a portion of the dielectric layer 40. In some arrangements, the portion 50p5 tapers toward the substrate 20 in a cross-sectional view perspective. In some arrangements, a lateral surface of the bonding element 330 (or the solder element) includes a first portion adjacent to the substrate 10, a second portion adjacent to the substrate 20, and a third portion (also referred to as “a middle portion”) between the first portion and the second portion. The third portion may be concave toward an inner part of the bonding element 330. In some arrangements, the third portion of the lateral surface of the bonding element 330 is exposed to an air gap (e.g., the gap G3).

In some arrangements, the bonding element 340 connects to and contacts the barrier layers 130 and 230. In some arrangements, the portion 50p7 extends into the recess 40r7, and the portion 50p8 extends into the recess 40r8. In some arrangements, the portion 50p7 of the dielectric layer 50 is partially spaced apart from the dielectric layer 40 by a gap G6. In some arrangements, the gap G6 is filled with air. The gap G6 (or the voids) may be spaced apart from other gaps (or voids). The gap G6 may be referred to as an air gap, a void, an empty space, or the like. In some arrangements, the portion 50p8 of the dielectric layer 50 is partially spaced apart from the dielectric layer 40 by a gap G7. In some arrangements, the gap G7 (or the void) is defined by and between the dielectric layers 40 and 50. In some arrangements, the gap G7 is filled with air. The gap G7 may be referred to as an air gap, a void, an empty space, or the like. In some arrangements, the bonding element 340 tapers toward the substrate 10. In some arrangements, the bonding element 340 vertically overlaps the portion 50p7. In some arrangements, the RDL pad 220 vertically overlaps the portion 50p7. In some arrangements, the portion 50p7 contacts a portion of the barrier layer 130. In some arrangements, the portion 50p8 extends under a portion of the dielectric layer 40 (or the dam structure). In some arrangements, the portion 50p8 extends between the substrate 10 and the dielectric layer 40. In some arrangements, the portion 50p8 extends between the base layer 100 and a portion of the dielectric layer 40. In some arrangements, the portion 50p8 tapers toward the substrate 20 in a cross-sectional view perspective. In some arrangements, a lateral surface of the bonding element 340 (or the solder element) includes a first portion adjacent to the substrate 10, a second portion adjacent to the substrate 20, and a third portion (also referred to as “a middle portion”) between the first portion and the second portion. The third portion may be concave toward an inner part of the bonding element 340. In some arrangements, the pad structure (e.g., the RDL pad 120 and the barrier layer 130) has an upper surface connected to and partially exposed by the bonding element 340.

In some arrangements, the bonding element 350 connects to and contacts the barrier layers 130 and 230. In some arrangements, the portion 50p9 extends into the recess 40r9, and the portion 50p10 extends into the recess 40r10. In some arrangements, the portion 50p9 of the dielectric layer 50 is partially spaced apart from the dielectric layer 40 by a gap G8. The gap G8 may extend over a portion of a top surface of the dam structure 40p next to the recess 40r9. In some arrangements, the gap G8 is filled with air. The gap G8 may be referred to as an air gap, a void, an empty space, or the like. In some arrangements, a portion of the bonding element 350 tapers toward the substrate 10, and a portion of the bonding element 350 tapers toward the substrate 20. In some arrangements, a sidewall of the bonding element 350 is spaced apart from a portion of the dielectric layer 50 by a gap G4. The gap G4 may be defined by the dielectric layer 50 and a recess of the bonding element 350. In some arrangements, a portion of the barrier layer 230 is exposed to the gap G4. In some arrangements, the gap G4 is filled with air. The gap G4 may be referred to as an air gap, a void, an empty space, or the like. In some arrangements, the bonding element 350 defines a gap 350g between the RDL pad 120 of the substrate 10 and the RDL pad 220 of the substrate 20. In some arrangements, a portion 50p9′ of the dielectric layer 50 extends into the gap 350g. In some arrangements, the bonding element 350 vertically overlaps the portion 50p9. In some arrangements, the RDL pad 220 vertically overlaps the portion 50p9. In some arrangements, the portion 50p10 extends under a portion of the dielectric layer 40 (or the dam structure). In some arrangements, the portion 50p10 extends between the substrate 10 and the dielectric layer 40. In some arrangements, the portion 50p10 extends between the base layer 100 and a portion of the dielectric layer 40. In some arrangements, the portion 50p10 tapers toward the substrate 20 in a cross-sectional view perspective. In some arrangements, a lateral surface of the bonding element 350 (or the solder element) includes a first portion adjacent to the substrate 10, a second portion adjacent to the substrate 20, and a third portion (also referred to as “a middle portion”) between the first portion and the second portion. The third portion may be concave toward an inner part of the bonding element 350. In some arrangements, the dielectric layer 50 partially extends into the third portion (e.g., the gap 350g) of the lateral surface of the bonding element 350.

In some arrangements, the bonding element 360 connects to and contacts the barrier layers 130 and 230. In some arrangements, the portion 50p11 extends into the recess 40r11, and the portion 50p12 extends into the recess 40r12. In some arrangements, a portion of the bonding element 360 tapers toward the substrate 10, and a portion of the bonding element 360 tapers toward the substrate 20. In some arrangements, the bonding element 360 includes a metal portion and an oxide portion 360B embedded in the metal portion. The metal portion may include a metal element, and the oxide portion 360B may include an oxide of the metal element. In some arrangements, a sidewall of the bonding element 360 is spaced apart from a portion of the dielectric layer 50 by a gap G5. The gap G5 may be defined by the dielectric layer 50 and a recess of the bonding element 360. In some arrangements, the gap G5 is filled with air. The gap G5 may be referred to as an air gap, a void, an empty space, or the like. In some arrangements, the bonding element 360 vertically overlaps the portion 50p11. In some arrangements, the RDL pad 220 vertically overlaps the portion 50p11. In some arrangements, the portion 50p11 extends under a portion of the dielectric layer 40 (or the dam structure). In some arrangements, the portion 50p11 extends between the substrate 10 and the dielectric layer 40. In some arrangements, the portion 50p11 extends between the base layer 100 and a portion of the dielectric layer 40. In some arrangements, the portion 50p11 tapers toward the substrate 20 in a cross-sectional view perspective.

According to some arrangements of the present disclosure, the dielectric layer 50 encapsulates the bonding elements 310, 320, 330, 340, 350, and 360 and is directly connected to the dielectric layer 40, and the dielectric layer 50 further include at least a portion (or a protrusion) extending into at least a recess of the dielectric layer 40. With the above structural design, the dielectric layers 40 and 50 can be bonded to each other by the protrusions locking with the recesses. Therefore, the adhesion between the dielectric layers 40 and 50 can be relatively strong, and thus the stability and the reliability of the bonding structure 1 can be improved.

In addition, according to some arrangements of the present disclosure, the protrusion of the dielectric layer 50 further extending between a portion of the dielectric layer 40 and the base layer 100, thus the protrusion of the dielectric layer 50 is interlocked with the recess of the dielectric layer 40. Therefore, the adhesion between the dielectric layers 40 and 50 is achieved by not only chemical bonds between the dielectric layers 40 and 50 but also the mechanical connection mechanism that provides additional bonding force. Therefore, the bonding strength between the dielectric layers 40 and 50 can be relatively strong, and thus the stability and the reliability of the bonding structure 1 can be further improved.

Moreover, according to some arrangements of the present disclosure, the bonding structure includes the dielectric layers 40 and 50 for bonding the substrates 10 and 20 and encapsulating the bonding elements 310, 320, 330, 340, 350, and 360 (or the solder bumps) instead of using an underfill to encapsulate the bonding elements 310, 320, 330, 340, 350, and 360 (or the solder bumps). Therefore, the issue of voids formed in the underfill resulted from remained flux from deoxidizing bonding surfaces of the bonding elements (or the solder bumps) can be avoided. In addition, since an underfill to fill between the bonding elements 310, 320, 330, 340, 350, and 360 (or the solder bumps) is omitted, and the dielectric layers 40 and 50 are formed together with the formation of the bonding elements 310, 320, 330, 340, 350, and 360 (or the solder bumps), the issue of failing to fill small gaps between bonding elements 310, 320, 330, 340, 350, and 360 (or the solder bumps) having a small pitch with an underfill can be avoided, thus the bonding elements 310, 320, 330, 340, 350, and 360 (or the solder bumps) having a small pitch can be nicely encapsulated and protected by a dielectric structure (e.g., the dielectric layers 40 and 50). That is, a hybrid bond structure including solders instead of metal pad can be achieved for fine pitch bonding structures. Therefore, the reliability of the bonding structure 1 is improved, and the yield is increased.

Furthermore, according to some arrangements of the present disclosure, the bonding elements 310, 320, 330, 340, 350, and 360 are spaced apart from each other by the dam structure (i.e., the dielectric layer 40). Therefore, the bonding elements 310, 320, 330, 340, 350, and 360 can be prevented from contacting each other when being melted during a reflow operation for forming the bonding elements 310, 320, 330, 340, 350, and 360 having a small pitch, and thus undesirably short-circuit between the bonding elements 310, 320, 330, 340, 350, and 360 having a small pitch can be prevented, and the processing window of the reflow operation can be enlarged, which can increase the yield.

FIG. 1A is a top view of a portion of a bonding structure in accordance with some arrangements of the present disclosure. In some arrangements, FIG. 1A is a top view of a portion 1A of the bonding structure 1 in FIG. 1. In some arrangements, the portion 1A shows a cross-section along a line 1-1′ in FIG. 1A.

In some arrangements, the bonding element 310 is disposed in a recess 40R1 of the dielectric layer 40, and the recess 40R1 is formed by the recesses 40r1 and 40r2 that connect to each other. In some arrangements, the recess 40R1 surrounds the bonding element 310 from a top view perspective. In some arrangements, the portions 50p1 and 50p2 of the dielectric layer 50 connect to each other to form a protrusion 50P1. In some arrangements, the protrusion 50P1 surrounds the bonding element 310 from a top view perspective. In some arrangements, an edge of the protrusion 50P1 may protrude beyond a portion of an edge of the recess 40R1.

In some arrangements, the bonding element 320 is disposed in a recess 40R2 of the dielectric layer 40, and the recess 40R2 is formed by the recesses 40r3 and 40r4 that connect to each other. In some arrangements, the recess 40R2 surrounds the bonding element 320 from a top view perspective. In some arrangements, the portions 50p3 and 50p4 of the dielectric layer 50 connect to each other to form a protrusion 50P2. In some arrangements, the protrusion 50P2 surrounds the bonding element 320 from a top view perspective. In some arrangements, an edge of the protrusion 50P2 may protrude beyond a portion of an edge of the recess 40R2.

In some arrangements, a distance between the protrusions 50P1 and 50P2 is different from a distance between the recesses 40R1 and 40R2.

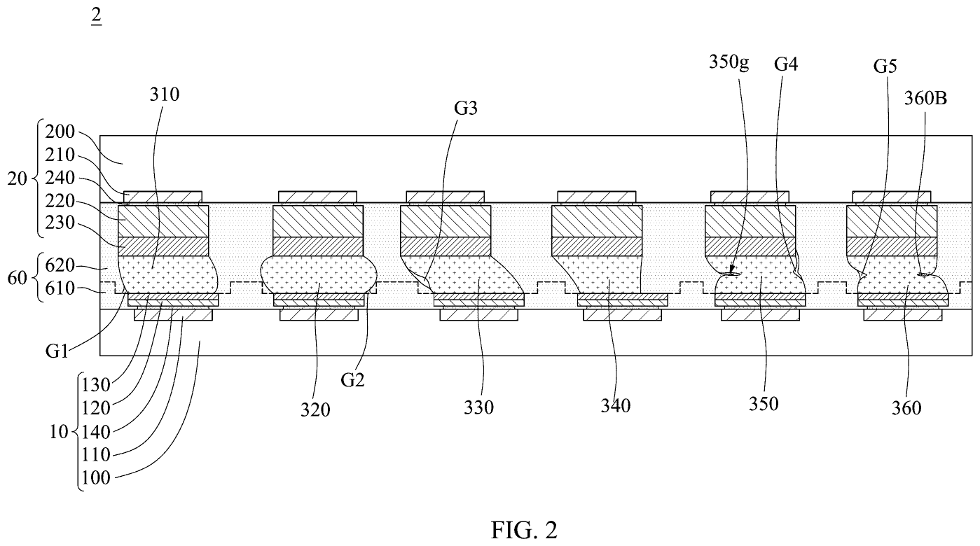

FIG. 2 is a cross-section of a bonding structure 2 in accordance with some arrangements of the present disclosure. The bonding structure 2 is similar to the bonding structure 1 in FIG. 1, and the differences therebetween are described as follows.

In some arrangements, the bonding structure 2 includes a dielectric layer 60 that encapsulates the RDL pads 120 and 220, the barrier layers 130 and 230, the seed layers 140 and 240, and the bonding elements 310, 320, 330, 340, 350, and 360. In some arrangements, the dielectric layer 60 is formed by bonding dielectric layers 610 and 620 to each other. In some arrangements, the dielectric layers 610 and 620 are formed of the same material, and thus no interface within the dielectric layer 60 may be observed.

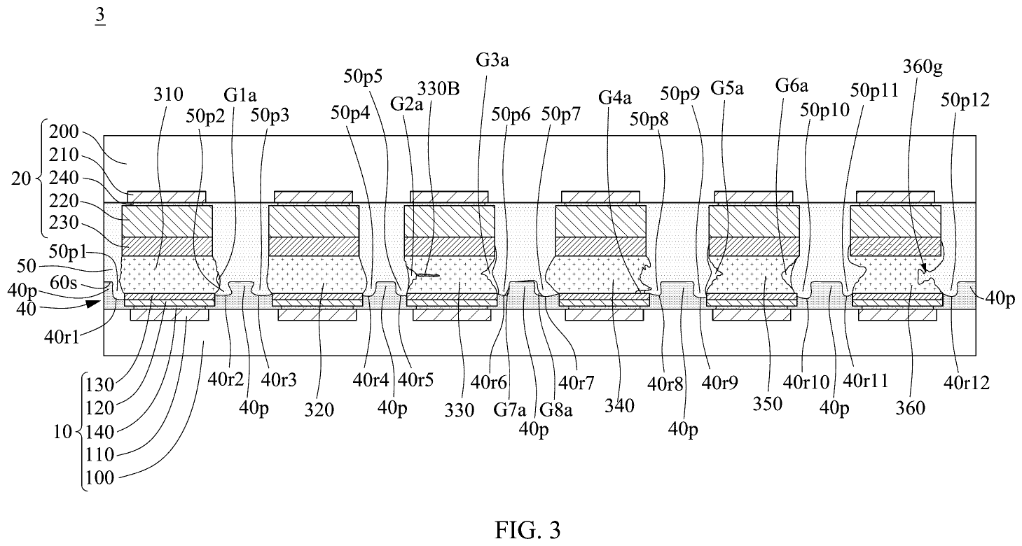

FIG. 3 is a cross-section of a bonding structure 3 in accordance with some arrangements of the present disclosure. The bonding structure 3 is similar to the bonding structure 1 in FIG. 1, and the differences therebetween are described as follows.

In some arrangements, the bonding element 310 connects to and contacts the barrier layers 130 and 230. In some arrangements, the portion 50p1 extends into the recess 40r1, and the portion 50p2 extends into the recess 40r2. In some arrangements, the bonding element 310 is partially spaced apart from the dielectric layer 50 by a gap G1a. In some arrangements, the gap G1a is filled with air. The gap G1a may be referred to as an air gap, a void, an empty space, or the like. In some arrangements, the bonding element 310 vertically overlaps the portion 50p2. In some arrangements, the RDL pad 220 vertically overlaps the portion 50p2. In some arrangements, the portion 50p2 extends under a portion of the dielectric layer 40 (or the dam structure). In some arrangements, the portion 50p2 extends between the substrate 10 and the dielectric layer 40. In some arrangements, the portion 50p2 extends between the base layer 100 and a portion of the dielectric layer 40. In some arrangements, the portion 50p2 tapers toward the substrate 20 in a cross-sectional view perspective.

In some arrangements, the bonding element 320 connects to and contacts the barrier layers 130 and 230. In some arrangements, the portion 50p3 extends into the recess 40r3, and the portion 50p4 extends into the recess 40r4. In some arrangements, the portion 50p3 extends under a portion of the dielectric layer 40 (or the dam structure). In some arrangements, the portion 50p3 extends between the substrate 10 and the dielectric layer 40. In some arrangements, the portion 50p3 extends between the base layer 100 and a portion of the dielectric layer 40. In some arrangements, the bonding element 320 vertically overlaps the portion 50p3. In some arrangements, the portion 50p3 tapers toward the substrate 20 in a cross-sectional view perspective. In some arrangements, the portion 50p4 contacts a portion of the barrier layer 130.

In some arrangements, the bonding element 330 connects to and contacts the barrier layers 130 and 230. In some arrangements, the portion 50p5 extends into the recess 40r5, and the portion 50p6 extends into the recess 40r6. In some arrangements, the bonding element 330 includes a metal portion and an oxide portion 330B embedded in the metal portion. The metal portion may include a metal element, and the oxide portion 330B may include an oxide of the metal element. In some arrangements, the bonding element 330 is partially spaced apart from the dielectric layer 50 by gaps G2a and G3a. In some arrangements, opposite sidewalls of the bonding element 330 are exposed to the gaps G2a and G3a. In some arrangements, the oxide portion 330B is exposed to the gap G2a. In some arrangements, a portion of the dielectric layer 50 is exposed to the gap G2a. In some arrangements, the portion 50p6 of the dielectric layer 50 is partially spaced apart from the dielectric layer 40 by a gap G7a. In some arrangements, the gaps G2a, G3a, and G7a are filled with air. The gaps G2a, G3a, and G7a may be referred to as air gaps, voids, empty spaces, or the like. In some arrangements, the portion 50p5 contacts a portion of the barrier layer 130.

In some arrangements, the bonding element 340 connects to and contacts the barrier layers 130 and 230. In some arrangements, the portion 50p7 extends into the recess 40r7, and the portion 50p8 extends into the recess 40r8. In some arrangements, the portion 50p7 of the dielectric layer 50 is partially spaced apart from the dielectric layer 40 by a gap G8a. The gap G8a may extend over a portion of a top surface of the dam structure 40p next to the recess 40r7. In some arrangements, the gap G8a is filled with air. The gap G8a may be referred to as an air gap, a void, an empty space, or the like. In some arrangements, the bonding element 340 vertically overlaps the portion 50p7. In some arrangements, the RDL pad 220 vertically overlaps the portion 50p7. In some arrangements, the portion 50p8 extends under a portion of the dielectric layer 40 (or the dam structure). In some arrangements, the portion 50p8 extends between the substrate 10 and the dielectric layer 40. In some arrangements, the portion 50p8 extends between the bonding element 340 and the RDL pad 120. In some arrangements, the portion 50p8 extends between the bonding element 340 and the barrier layer 130. In some arrangements, the portion 50p8 is exposed to a gap G4. In some arrangements, the RDL pad 120 is partially spaced apart from the bonding element 340 by the gap G4a. In some arrangements, the gap G4a is filled with air. The gap G4a may be referred to as an air gap, a void, an empty space, or the like.

In some arrangements, the bonding element 350 connects to and contacts the barrier layers 130 and 230. In some arrangements, the portion 50p9 extends into the recess 40r9, and the portion 50p10 extends into the recess 40r10. In some arrangements, the bonding element 350 is partially spaced apart from the dielectric layer 50 by gaps G5a and G6a. In some arrangements, opposite sidewalls of the bonding element 330 are exposed to the gaps G5a and G6a. In some arrangements, the gaps G5a and Goa are filled with air. The gaps G5a and Goa may be referred to as air gaps, voids, empty spaces,

In some arrangements, the bonding element 360 connects to and contacts the barrier layers 130 and 230. In some arrangements, the portion 50p11 extends into the recess 40r11, and the portion 50p12 extends into the recess 40r12. In some arrangements, the bonding element 360 defines a gap 360g between the RDL pad 120 and the RDL pad 220. In some arrangements, a portion of the dielectric layer 50 extends into the gap 360g.

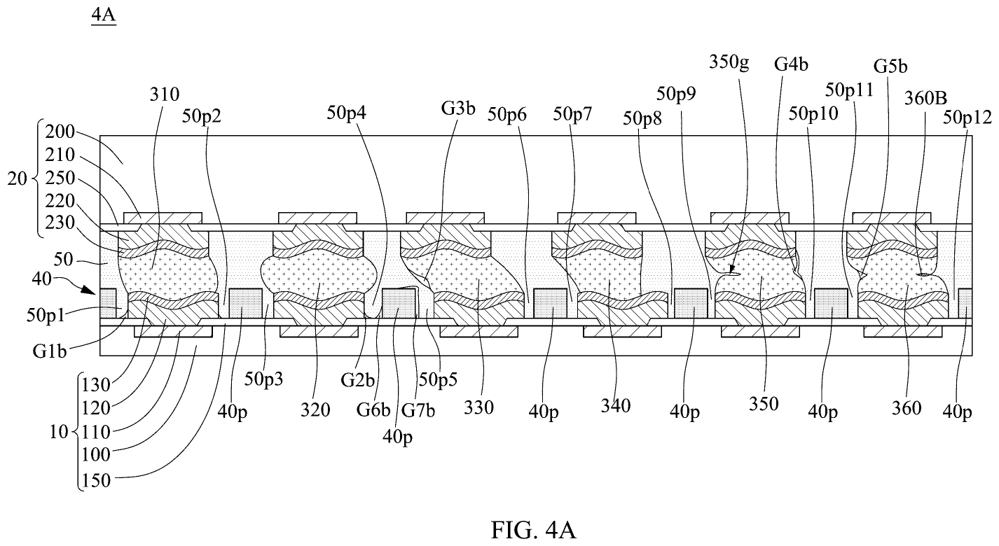

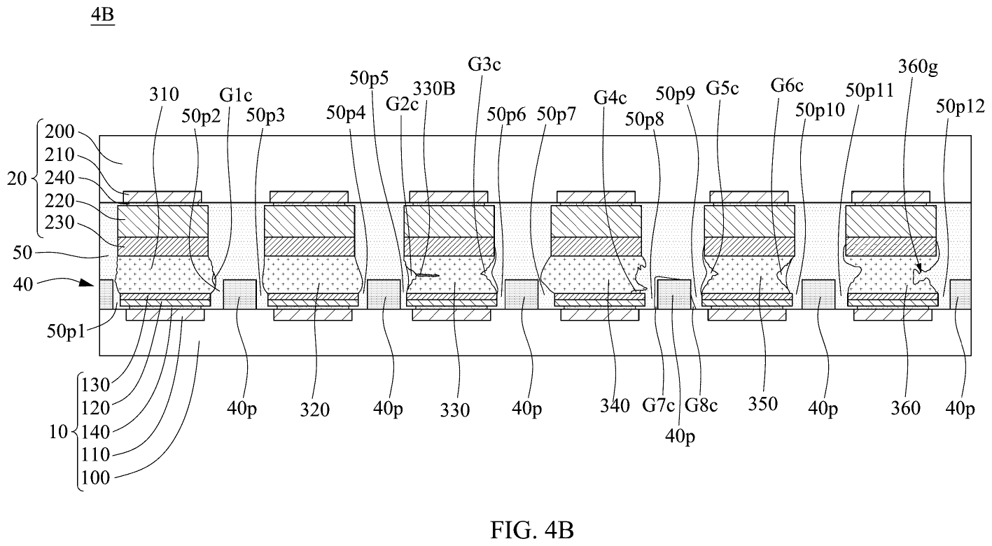

FIG. 4A is a cross-section of a bonding structure 4A in accordance with some arrangements of the present disclosure. The bonding structure 4A is similar to the bonding structure 1 in FIG. 1, and the differences therebetween are described as follows.

In some arrangements, the substrate 10 further includes a dielectric layer 150 between the dielectric layer 40 and the base layer 100. The dielectric layer 40 may include dam structures 40p. The dielectric layers 40 and 150 collectively define spaces for accommodating portions of the bonding elements 310, 320, 330, 340, 350, and 360 and portions of the dielectric layer 50. In some arrangements, the RDL pads 120 and the barrier layers 130 contact the dielectric layer 50. In some arrangements, the substrate 20 further includes a dielectric layer 250 between the base layer 200 and the dielectric layer 50.

In some arrangements, gaps G1b and G2b are exposed to the dielectric layer 150. In some arrangements, gaps G3b, G4b, and G5b are formed between the dielectric layer 50 and the bonding elements 330, 340, and 350. In some arrangements, gaps G6b and G7b are formed between the dielectric layer 50 and the dam structure 40p of the dielectric layer 40.

FIG. 4B is a cross-section of a bonding structure 4B in accordance with some arrangements of the present disclosure. The bonding structure 4B is similar to the bonding structure 1 in FIG. 1, and the differences therebetween are described as follows.

In some arrangements, the base layer 100 and the dielectric layer 40 collectively define spaces for accommodating portions of the bonding elements 310, 320, 330, 340, 350, and 360 and portions of the dielectric layer 50. The dielectric layer 40 may include dam structures 40p. In some arrangements, the RDL pads 120, the barrier layers 130, and the seed layers 140 contact the dielectric layer 50.

In some arrangements, gaps G1c, G2c, G3c, G5c, and G6c are exposed to the dielectric layer 150. In some arrangements, a gap G3c is formed between the barrier layer 130 and the bonding element 340. In some arrangements, gaps G7c and G8c are formed between the dielectric layer 50 and the dam structure 40p of the dielectric layer 40.

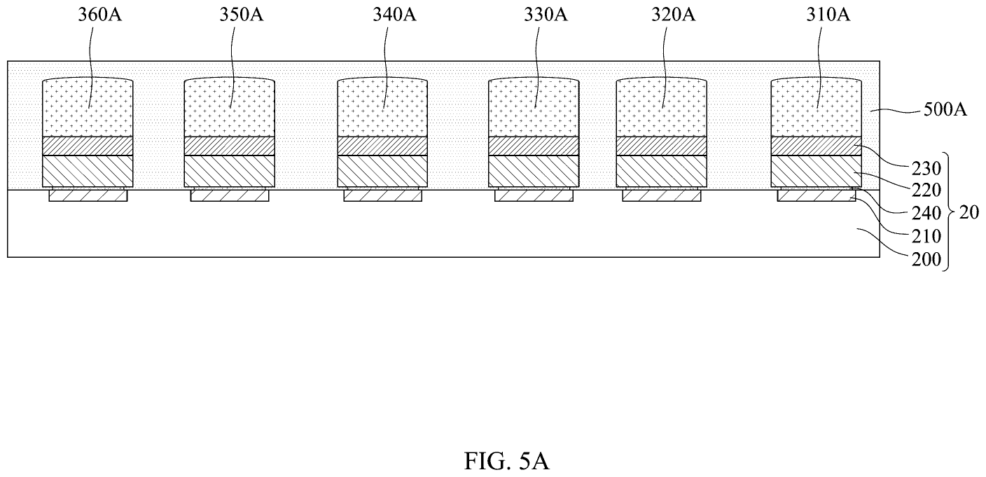

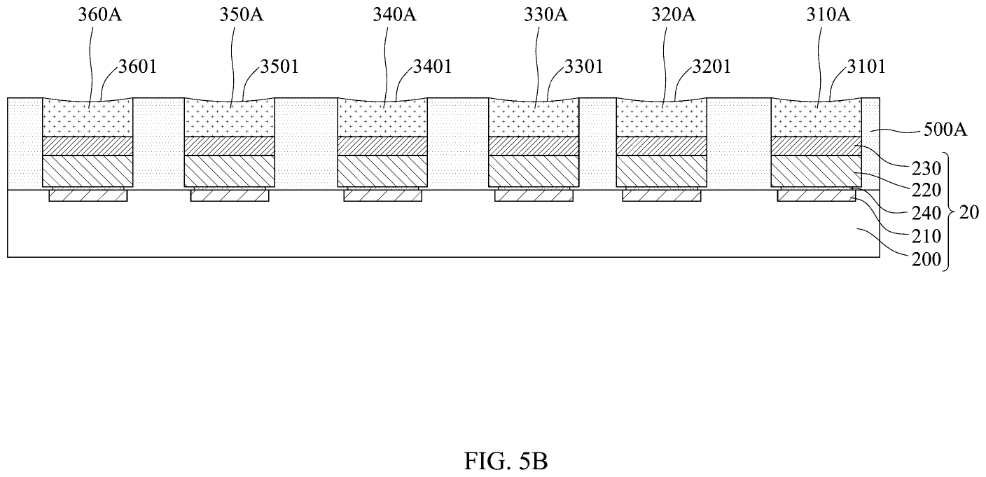

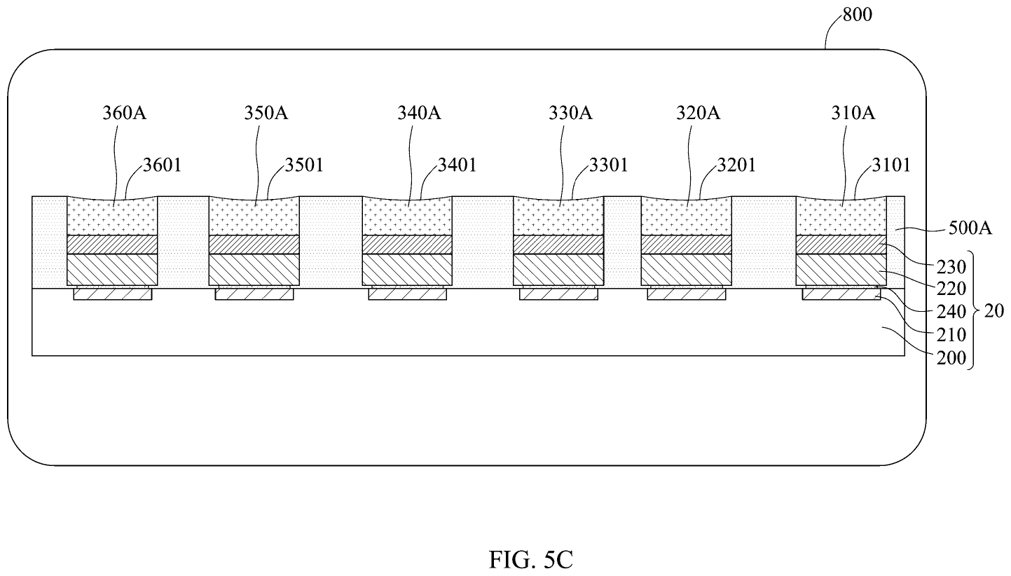

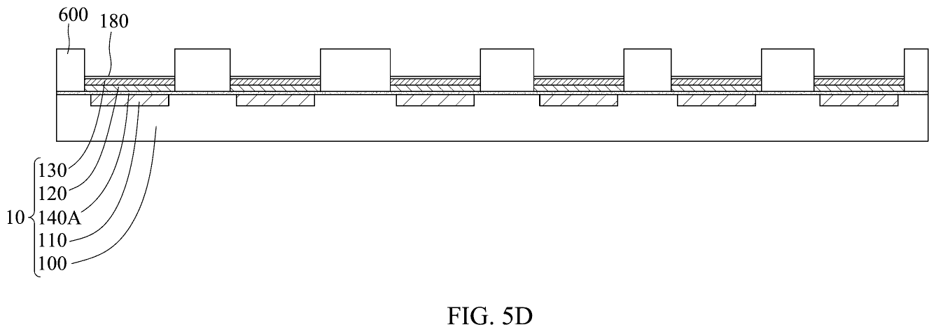

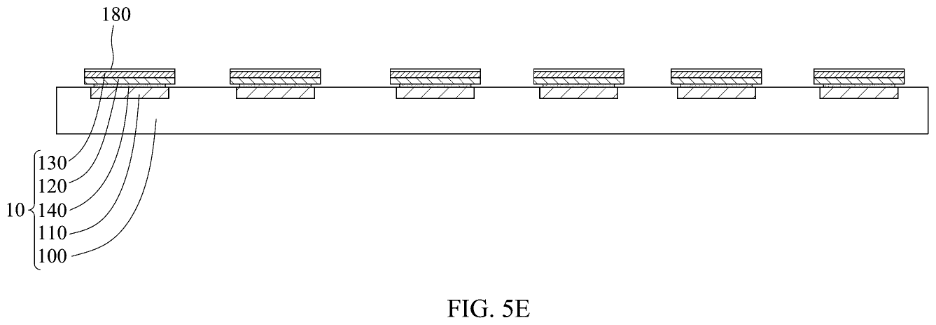

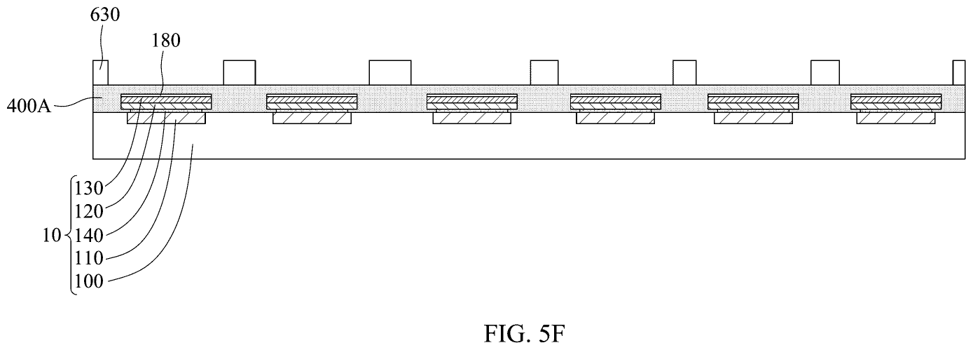

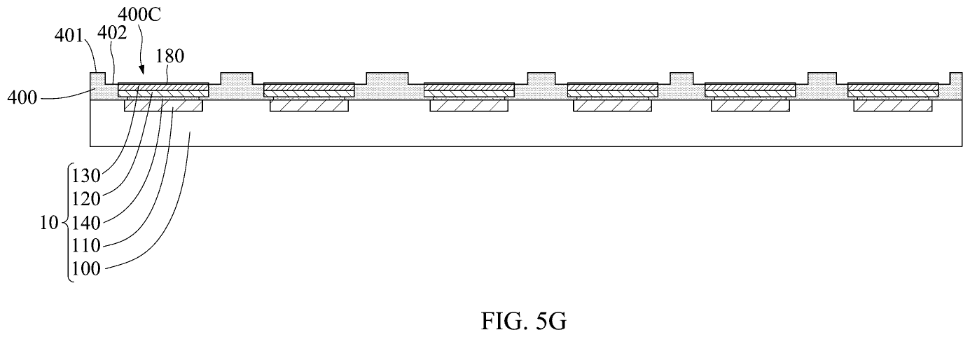

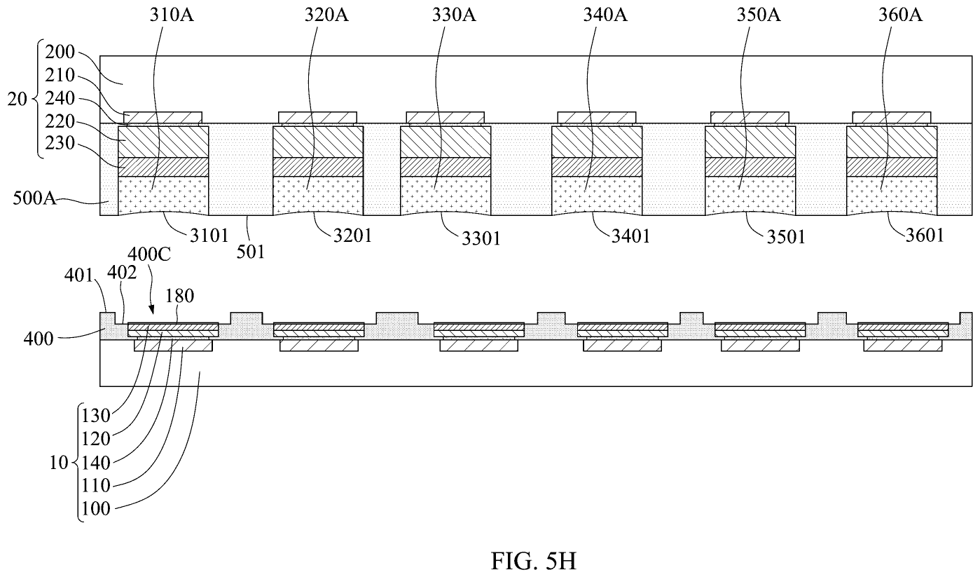

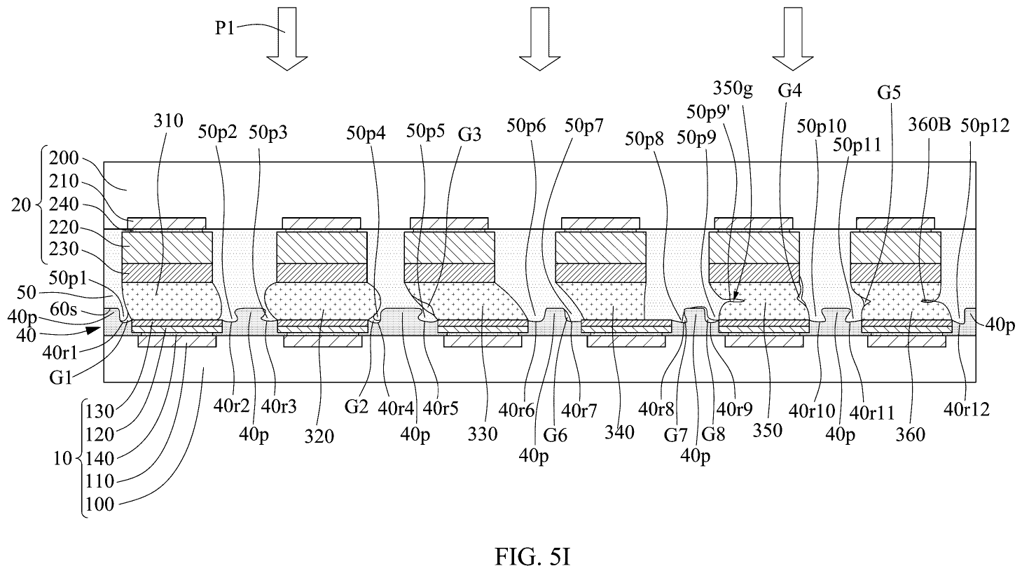

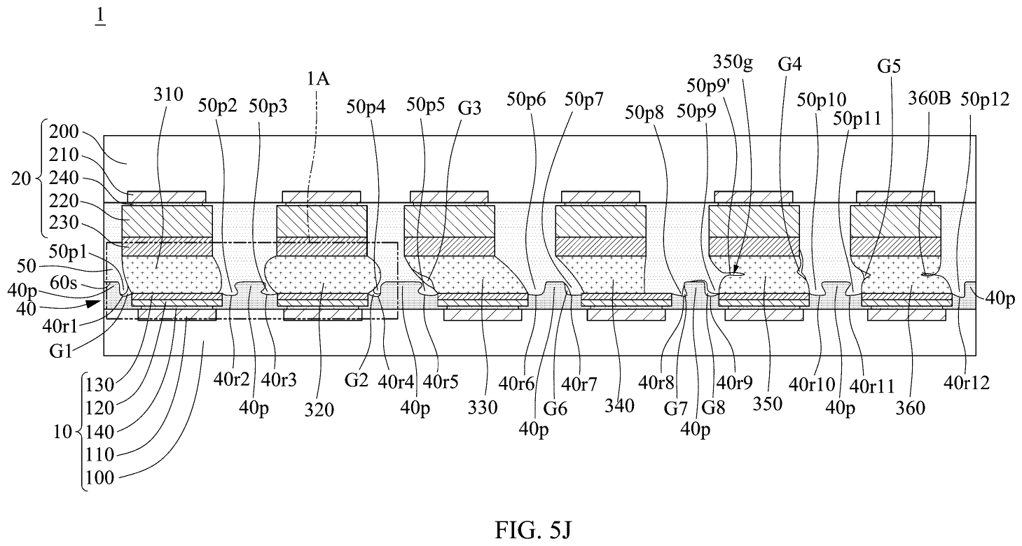

FIG. 5A to FIG. 5J illustrate various stages of an exemplary method of forming a bonding structure 1 in accordance with some arrangements of the present disclosure.

Referring to FIG. 5A, a substrate 20 including a base layer 200, base pads 210, RDL pads 220, barrier layers 230, and seed layers 240 may be provided, bonding material layers 310A, 320A, 330A, 340A, 350A, and 360A may be disposed over the barrier layers 230, and a dielectric material layer 500A may be disposed over and covering the base pads 210 and the RDL pads 220, the barrier layers 230, the seed layers 240, and the bonding material layers 310A, 320A, 330A, 340A, 350A, and 360A. The bonding material layers 310A, 320A, 330A, 340A, 350A, and 360A may include solder materials. The dielectric material layer 500A may include PI, NCF, or the like. The base pads 210 and the RDL pads 220, the barrier layers 230, and the seed layers 240 may be formed by plating. In some arrangements, a thermal operation (e.g., a reflow operation) is not performed on the bonding material layers 310A, 320A, 330A, 340A, 350A, and 360A (or the solder bumps), and thus the top surfaces of the bonding material layers 310A, 320A, 330A, 340A, 350A, and 360A are relatively flat instead of having convex curved surface (e.g., the convex curved surfaces of solder balls).

Referring to FIG. 5B, portions of the dielectric material layer 500A and the bonding material layers 310A, 320A, 330A, 340A, 350A, and 360A may be removed to exposed top surfaces 3101, 3201, 3301, 3401, 3501, and 3601 of the bonding material layers 310A, 320A, 330A, 340A, 350A, and 360A. The top surface of the dielectric material layer 500A may be substantially aligned with the top surfaces 3101, 3201, 3301, 3401, 3501, and 3601 of the bonding material layers 310A, 320A, 330A, 340A, 350A, and 360A. The removal may be performed by a grinding operation. For example, a fly-cut operation may be performed to partially remove the dielectric material layer 500A and the bonding material layers 310A, 320A, 330A, 340A, 350A, and 360A. In some arrangements, the extent of dishing of the surfaces 3101, 3201, 3301, 3401, 3501, and 3601 is about 100 nm or less. In some arrangements, the surfaces 3101, 3201, 3301, 3401, 3501, and 3601 are concave curved surfaces, and a difference between elevations of each of the surfaces 3101, 3201, 3301, 3401, 3501, and 3601 is about 100 nm or less. In some arrangements, a total thickness variation (TTV) of the surfaces 3101, 3201, 3301, 3401, 3501, and 3601 is less than 1μ m.

According to some arrangements of the present disclosure, bonding elements are formed by heating and melting the bonding material layers 310A, 320A, 330A, 340A, 350A, and 360A in subsequent processes, and therefore the extend of dishing that is about 100 nm and the TTV that is less than 1 μm is acceptable. Therefore, the fly-cut operation is used instead of using a CMP operation can reduce cost.

In addition, according to some arrangements of the present disclosure, the bonding material layers 310A, 320A, 330A, 340A, 350A, and 360A are not heated and melted to form ball shapes, thus the cut surfaces 3101, 3201, 3301, 3401, 3501, and 3601 can have relatively large areas. Therefore, the bonding surfaces are relatively large, which is advantageous to increasing the bonding strength.

Referring to FIG. 5C, a de-oxidation operation may be performed on the surfaces 3101, 3201, 3301, 3401, 3501, and 3601 of the bonding material layers 310A, 320A, 330A, 340A, 350A, and 360A. In some arrangements, oxides (e.g., native oxides of the soldering materials) on the surfaces 3101, 3201, 3301, 3401, 3501, and 3601 may be removed by applying formic acid or flux over the surfaces 3101, 3201, 3301, 3401, 3501, and 3601. In some arrangements, the structure illustrated in FIG. 5B may be placed in a vacuum chamber 800, a formic acid solution may be sprayed over the surfaces 3101, 3201, 3301, 3401, 3501, and 3601 and react with the oxides to decompose the oxides. Then, decomposed products may be removed by vacuum. In some other arrangements, the surfaces 3101, 3201, 3301, 3401, 3501, and 3601 may be dipped into a flux solution allowing the flux to remove the oxides from the surfaces.

Referring to FIG. 5D, a substrate 10 including a base layer 100, base pads 110, and a seed layer 140A may be provided, a sacrificial pattern 600 may be disposed over the seed layer 140A, and RDL pads 120 and barrier layers 130 may be formed over the seed layer 140A and in openings defined by the sacrificial pattern 600. In some arrangements, a protective layer 180 may be formed over the barrier layers 130 to prevent them from being further oxidized. The protective layer 180 may be formed by plating. The protective layer 180 may be formed of or include gold (Au). The sacrificial pattern 600 may be or include a photoresist layer.

Referring to FIG. 5E, the sacrificial pattern 600 may be removed, and portions of the seed layer 140A exposed by the RDL pads 120 and the barrier layers 130 may be removed to form seed layers 140. In some arrangements, the sacrificial pattern 600 is removed by a stripping operation. In some arrangements, the portions of the seed layer 140A may be removed by an etching operation, and lateral surfaces of the seed layers 140 are recessed with respect to lateral surfaces of the RDL pads 120 and lateral surfaces of the barrier layers 130.

Referring to FIG. 5F, a dielectric material layer 400A may be formed over and covering the RDL pads 120, the barrier layers 130, and the protective layers 180, and a sacrificial pattern 630 may be disposed over the dielectric material layer 400A. In some arrangements, the dielectric material layer 400A may be or include PI. The sacrificial pattern 630 may be or include a photoresist layer.

Referring to FIG. 5G, portions of the dielectric material layer 400A may be removed to form a dielectric material layer 400 having openings 400C that exposed the protective layers 180, and the sacrificial pattern 630 may be removed. In some arrangements, the openings 400C are defined by an upper surface 401 and lower surfaces 402 of the dielectric material layer 400. In some arrangements, a size of the opening 400C is greater than a width of the protective layer 180, a width of the barrier layer 130, a width of the RDL pad 120, and a width of the seed layer 140. The dielectric material layer 400A may be partially removed by a dry etching operation. In some arrangements, the sacrificial pattern 630 is removed by a stripping operation.

Referring to FIG. 5H, the substrate 20 may be bonded to the substrate 10 with the bonding material layers 310A, 320A, 330A, 340A, 350A, and 360A facing the openings 400C of the dielectric material layer 400. Each of the widths of the bonding material layers 310A, 320A, 330A, 340A, 350A, and 360A may be less than a size (or a width) of each of the corresponding openings 400C.

Referring to FIG. 5I, a thermal operation PI may be performed to form bonding elements 310, 320, 330, 340, 350, and 360 that are connected to the RDL pads 120 and the barrier layers 130 thereon. In some arrangements, the protective layers 180 may be melted into the bonding elements 310, 320, 330, 340, 350, and 360. In some arrangements, the thermal operation may be or include a reflow operation. The bonding material layers 310A, 320A, 330A, 340A, 350A, and 360A may melt and soften to deform and flow toward the RDL pads 120 by the thermal operation. In some arrangements, the dielectric material layers 400 and 500A may soften and connect to each other by the thermal operation.

In some arrangements, as the temperature raises during the initial stage of the thermal operation, the dielectric material layers 400 and 500A may soften and deform. In some arrangements, some portions of the dielectric material layer 500A may apply forces on some regions or areas of the dielectric material 400 when they contact, and thus some protrusions (e.g., the portions 50p2, 50p3, 50p5, 50p8, 50p10, and 50p11) of the dielectric material layer 500A may press against the dielectric material layer 400 and protrude into some regions or areas of the dielectric material layer 400 to form recesses that extend further under portions of the dielectric material layer 400. In some arrangements, as the temperature raises to the melting point of the bonding material layers 310A, 320A, 330A, 340A, 350A, and 360A (e.g., solder materials), the bonding material layers 310A, 320A, 330A, 340A, 350A, and 360A may deform and form the bonding elements 310, 320, 330, 340, 350, and 360.

Referring to FIG. 5J, a curing operation may be performed to cure the deformed dielectric material layers 400 and 500A to form dielectric layers 40 and 50 that are connected to each other. As such, the bonding structure 1 may be formed.

In some arrangements, when the dielectric material layers 400 and 500A are formed of the same material, a monolithic dielectric layer 60 may be formed, as shown in FIG. 2. In some arrangements, an interface between the dielectric layers 610 and 620 formed from the dielectric material layers 400 and 500A may be invisible to human eyes or to electro-microscopy technique.

In some arrangements, when the dielectric material layers 400 and 500A are bonded by a thermo-compression bonding operation, the lateral surfaces of the bonding elements 310, 320, 330, 340, 350, and 360 may be less smooth or even having recesses or gaps, as shown in FIG. 3

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A bonding structure, comprising:
a first substrate;
a dielectric layer over the first substrate;
a second substrate over the first substrate;
a reflowable element connecting the first substrate to the second substrate; and
a dielectric adhesive element encapsulating the reflowable element and partially horizontally overlapping the dielectric layer.

2. The bonding structure as claims in claim 1, wherein an interface between the dielectric layer and the dielectric adhesive element comprises a wavy profile in a cross-sectional view perspective.

3. The bonding structure as claims in claim 2, wherein the first substrate comprises a first pad structure connected to the reflowable element and horizontally overlapping the dielectric adhesive element, and the second substrate comprises a second pad structure covered by the dielectric adhesive element in a horizontal direction.

4. The bonding structure as claims in claim 1, wherein a void is defined by and between the dielectric layer and the dielectric adhesive element.

5. The bonding structure as claims in claim 4, wherein the reflowable element is exposed to the void.

6. The bonding structure as claimed in claim 1, wherein a softening temperature of the dielectric adhesive element is lower than a melting point of the reflowable element.

7. The bonding structure as claimed in claim 6, wherein the dielectric adhesive element is free of a filler.

8. The bonding structure as claimed in claim 1, further comprising a plurality of the reflowable elements, wherein the dielectric adhesive element comprises a portion extending between the reflowable elements and contacting the dielectric layer.

9. The bonding structure as claimed in claim 8, wherein the dielectric layer comprises a dam structure contacting the dielectric adhesive element and configured to compress the dielectric adhesive element to increase a cover rate of the dielectric adhesive element over the first substrate and the second substrate.

10. The bonding structure as claimed in claim 8, wherein the portion of the dielectric adhesive element extends into a gap defined by the reflowable element and between the first substrate and the second substrate.

11. A bonding structure, comprising:
a first substrate;
a second substrate over the first substrate;
a reflowable element connecting the first substrate to the second substrate;
a first dielectric layer extending from the second substrate towards the first substrate; and
a second dielectric layer connected to the first dielectric layer and comprising a dam structure configured to compensate for an extension amount of the first dielectric layer to reduce a formation of voids.

12. The bonding structure as claimed in claim 11, wherein the reflowable element is partially spaced apart from a protrusion of the first dielectric layer by a first void.

13. The bonding structure as claimed in claim 12, wherein the first void is filled with air.

14. The bonding structure as claimed in claim 12, wherein the first dielectric layer is partially spaced apart from the second dielectric layer by a second void, and the second void is spaced apart from the first void.

15. The bonding structure as claimed in claim 11, wherein the reflowable element comprises a metal portion and an oxide portion embedded in the metal portion, and a sidewall of the reflowable element and the metal portion are exposed to a first void.

16. The bonding structure as claimed in claim 15, wherein a portion of the first dielectric layer is exposed to the first void.

17. A bonding structure, comprising:
a first substrate;
a second substrate over the first substrate; and
a solder element connecting the first substrate to the second substrate, wherein a lateral surface of the solder element comprises a first portion adjacent to the first substrate, a second portion adjacent to the second substrate, and a third portion between the first portion and the second portion and concave toward an inner part of the solder element.

18. The bonding structure as claimed in claim 17, wherein the first substrate comprises a pad structure having an upper surface connected to and partially exposed by the solder element.

19. The bonding structure as claimed in claim 17, further comprising a dielectric layer between the first substrate and the second substrate and partially extending into the third portion of the lateral surface of the solder element.

20. The bonding structure as claimed in claim 17, wherein the third portion of the lateral surface of the solder element is exposed to an air gap.
